(19) United States
(12) Patent Application Publication
(10) Pub. No.: US 2025/0105215 A1
(43) Pub. Date: Mar. 27, 2025

(54) SEMICONDUCTOR PACKAGES AND ELECTRONIC SYSTEMS INCLUDING THE SAME

(71) Applicant: SAMSUNG ELECTRONICS CO., LTD., Suwon-si (KR)

(72) Inventors: Keumhyo KANG, Suwon-si (KR); Hongsoo KIM, Suwon-si (KR); Jeon Il LEE, Suwon-si (KR)

(21) Appl. No.: 18/624,892

(22) Filed: Apr. 2, 2024

(30) Foreign Application Priority Data
Sep. 25, 2023 (KR) 10-2023-0128315

(51) Int. Cl. H01L 25/065; H01L 23/00; H01L 23/48; H10B 12/00

(52) U.S. Cl. CPC H01L 25/0657; H01L 23/481; H01L 24/08; H10B 12/50; H01L 24/16; H01L 24/80; H01L 2224/08145; H01L 2224/16225; H01L 2224/80895; H01L 2225/06541; H01L 2225/06551; H01L 2924/1436

(57) ABSTRACT

Disclosed are semiconductor packages and electronic systems. The semiconductor package comprises a first semiconductor chip that includes a first peripheral circuit structure and a first memory cell structure on the first peripheral circuit structure and a second semiconductor chip that includes a second peripheral circuit structure and a second memory cell structure on the second peripheral circuit structure. The first peripheral circuit structure includes a first substrate, a controller on the first substrate, and a first driver circuit on the first substrate. The second peripheral circuit structure includes a second substrate and a second driver circuit on the second substrate. The controller is electrically connected to the first driver circuit and the second driver circuit.

### REFERENCE TO RELATED APPLICATIONS

This U.S. nonprovisional application claims priority under 35 U.S.C. § 119 to Korean Patent Application No. 10-2023-0128315 filed on Sep. 25, 2023 in the Korean Intellectual Property Office, the disclosure of which is hereby incorporated by reference in its entirety.

### BACKGROUND OF THE INVENTION

The present inventive concepts relate to semiconductor packages and electronic systems, and more particularly, to semiconductor packages with a controller and electronic systems including the same.

Semiconductor devices attract attention as an essential element in electronics industry because of their properties such as compactness, multi-functionality, and/or low manufacturing cost. Semiconductor devices may encompass semiconductor memory devices storing logic data, semiconductor logic devices processing operations of logic data, and hybrid semiconductor devices having both memory and logic elements (devices).

Recently, high speed and low power consumption of electronic products may require semiconductor devices embedded in the electronic products to have an increased degree of integration to achieve high operating speed and/or lower operating voltage. However, an increase in integration of semiconductor devices may cause a reduction (e.g., a deterioration) in electrical properties and production yield of semiconductor devices. Therefore, many studies have been conducted to increase (e.g., to improve) electrical properties and production yield of semiconductor devices.

### SUMMARY OF THE INVENTION

Some embodiments of the present inventive concepts may provide semiconductor packages with improved electrical properties and increased reliability and electronic systems including the same.

According to some embodiments of the present inventive concepts, a semiconductor package may comprise: a first semiconductor chip that includes a first peripheral circuit structure and a first memory cell structure on the first peripheral circuit structure; and a second semiconductor chip that includes a second peripheral circuit structure and a second memory cell structure on the second peripheral circuit structure. The first peripheral circuit structure may include: a first substrate; a controller on the first substrate; and a first driver circuit on the first substrate. The second peripheral circuit structure may include: a second substrate; and a second driver circuit on the second substrate. The controller may be electrically connected to the first driver circuit and the second driver circuit.

According to some embodiments of the present inventive concepts, a semiconductor package may comprise: a first semiconductor chip that includes a first peripheral circuit structure and a first memory cell structure on the first peripheral circuit structure; and a second semiconductor chip that includes a second peripheral circuit structure and a second memory cell structure on the second peripheral circuit structure. The first memory cell structure may include a single-level-cell memory cell array. The second memory cell structure may include a multi-level-cell memory cell array.

According to some embodiments of the present inventive concepts, an electronic system may comprise: a first semiconductor chip that includes a first peripheral circuit structure and a first memory cell structure on the first peripheral circuit structure; and a second semiconductor chip that includes a second peripheral circuit structure and a second memory cell structure on the second peripheral circuit structure. The first peripheral circuit structure may include: a first lower peripheral dielectric layer; a first lower peripheral pad in the first lower peripheral dielectric layer; a first substrate on the first lower peripheral dielectric layer; a first through via that extends in the first substrate; a first upper peripheral dielectric layer on the first substrate; and a first upper peripheral pad in the first upper peripheral dielectric layer. The first memory cell structure may include: a first lower cell dielectric layer on the first upper peripheral dielectric layer; a first lower cell pad in the first lower cell dielectric layer; a first upper cell dielectric layer on the first lower cell dielectric layer; and a first upper cell pad in the first upper cell dielectric layer. The second peripheral circuit structure may include: a second lower peripheral dielectric layer on the first upper cell dielectric layer; a second lower peripheral pad in the second lower peripheral dielectric layer; a second substrate on the second lower peripheral dielectric layer; a second through via that extends in the second substrate; a second upper peripheral dielectric layer on the second substrate; and a second upper peripheral pad in the second upper peripheral dielectric layer. The second memory cell structure may include: a second lower cell dielectric layer on the second upper peripheral dielectric layer; and a second lower cell pad in the second lower cell dielectric layer. The first upper peripheral pad may overlap the first lower cell pad, the first upper cell pad, the second lower peripheral pad, the second upper peripheral pad, and the second lower cell pad in a direction. The first lower peripheral pad may not overlap any of the first upper peripheral pad, the first lower cell pad, the first upper cell pad, the second lower peripheral pad, the second upper peripheral pad, and the second lower cell pad in the direction. The direction may be perpendicular to a lower surface of the first lower peripheral dielectric layer.

### BRIEF DESCRIPTION OF DRAWINGS

FIG. 1 illustrates a block diagram showing an electronic system according to some embodiments.

FIG. 2 illustrates a block diagram showing a memory device according to some embodiments.

FIG. 3 illustrates a simplified cross-sectional view showing a semiconductor package according to some embodiments.

FIG. 4 illustrates a cross-sectional view showing a method of fabricating the semiconductor package according to FIG. 3.

FIG. 5 illustrates a simplified cross-sectional view showing a semiconductor package according to some embodiments.

FIGS. 6A and 6B illustrate cross-sectional views showing a method of fabricating the semiconductor package according to FIG. 5.

FIG. 7 illustrates a simplified cross-sectional view showing a semiconductor package according to some embodiments.

FIG. 8A illustrates a plan view showing a second semiconductor chip of a semiconductor package according to some embodiments.

FIG. 8B illustrates a plan view showing a first semiconductor chip of a semiconductor package according to some embodiments.

FIG. 8C illustrates a cross-sectional view taken along line A-A′ of FIGS. 8A and 8B.

### DETAILED DESCRIPTION

With reference to the accompanying drawings, the following will describe in detail a memory device and its fabrication method according to some embodiments of the present inventive concepts.

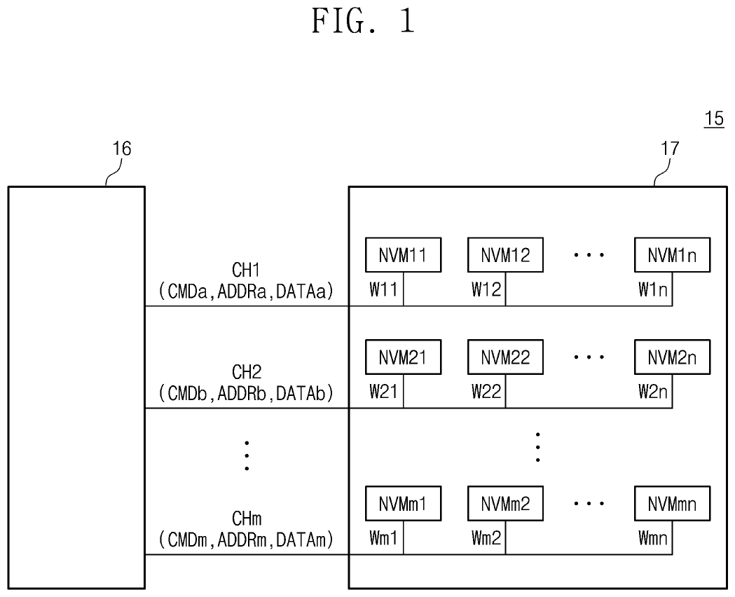

FIG. 1 illustrates a block diagram showing an electronic system according to some embodiments.

Referring to FIG. 1, an electronic system 15 may include a memory device 17 and a controller 16. The electronic system 15 may further include (e.g., may provide or may support) a plurality of channels CH1 to CHm, and the memory device 17 and the controller 16 may be connected (e.g., electrically connected) to each other through the plurality of channels CH1 to CHm. For example, the electronic system 15 may be implemented as a storage device such as a solid state drive (SSD), but is not limited thereto. It will be understood that when an element or layer is referred to as being “connected to”, or “coupled to”, another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection.

The memory device 17 may include nonvolatile memory devices NVM11 to NVMmn. Each of the nonvolatile memory devices NVM11 to NVMmn may be connected (e.g., electrically connected) through a corresponding way to one of the plurality of channels CH1 to CHm. For example, the nonvolatile memory devices NVM11 to NVM1n (among the nonvolatile memory devices NVM11 to NVMmn) may be connected (e.g., electrically connected) through ways W11 to W1n to a first channel CH1 (among the plurality of channels CH1 to CHm), and the nonvolatile memory devices NVM21 to NVM2n (among the nonvolatile memory devices NVM11 to NVMmn) may be connected (e.g., electrically connected) through ways W21 to W2n to a second channel CH2 (among the plurality of channels CH1 to CHm). In some embodiments, each of the nonvolatile memory devices NVM11 to NVMmn may be implemented as a (arbitrary or random) memory unit capable of operating in accordance with an individual command from the controller 16. For example, each of the nonvolatile memory devices NVM11 to NVMmn may be implemented as a chip or a die, but the present inventive concepts are not limited thereto.

The controller 16 may transceive signals with the memory device 17 through the plurality of channels CH1 to CHm. As used herein, the term “transceive” may mean “transmit” and/or “receive”. For example, the controller 16 may transmit commands CMDa to CMDm, addresses ADDRa to ADDRm, and data DATAa to DATAm to the memory device 17 through the plurality of channels CH1 to CHm, or may receive data DATAa to DATAm from the memory device 17 through the plurality of channels CH1 to CHm. As used herein, the term “and/or” includes any and all combinations of one or more of the associated listed items.

The controller 16 may use a channel (among the plurality of channels CH1 to CHm) to select one of the nonvolatile memory devices NVM11 to NVMmn that is connected (e.g., electrically connected) to the channel, and may transceive signals with the selected nonvolatile memory device. For example, the controller 16 may select the nonvolatile memory device NVM11 among the nonvolatile memory devices NVM11 to NVM1n (among the nonvolatile memory devices NVM11 to NVMmn) that are connected (e.g., electrically connected) to the first channel CH1 (among the plurality of channels CH1 to CHm). The controller 16 may transmit the command CMDa (among the commands CMDa to CMDm), the address ADDRa (among the addresses ADDRa to ADDRm), and the data DATAa (among the data DATAa to DATAm) to the nonvolatile memory device NVM11 through the first channel CH1, or may receive the data DATAa from the nonvolatile memory device NVM11 through the first channel CH1.

The controller 16 may transceive signals in parallel with the memory device 17 through different channels. For example, the controller 16 may transmit the command CMDb (among the commands CMDa to CMDm) to the memory device 17 through the second channel CH2 (among the plurality of channels CH1 to CHm) while transmitting the command CMDa (among the commands CMDa to CMDm) to the memory device 17 through the first channel CH1 (among the plurality of channels CH1 to CHm). For example, the controller 16 may receive the data DATAb (among the data DATAa to DATAm) from the memory device 17 through the second channel CH2 while receiving the data CMDa (among the data DATAa to DATAm) from the memory device 17 through the first channel CH1.

The controller 16 may control an overall operation of the memory device 17. The controller 16 may transmit signals to the plurality of channels CH1 to CHm to correspondingly control the nonvolatile memory devices NVM11 to NVMmn connected (e.g., electrically connected) to the plurality of channels CH1 to CHm. For example, the controller 16 may transmit the command CMDa (among the commands CMDa to CMDm) and the address ADDRa (among the addresses ADDRa to ADDRm) to the first channel CH1 (among the plurality of channels CH1 to CHm) to control a selected one of the nonvolatile memory devices NVM11 to NVMmn.

Each of the nonvolatile memory devices NVM11 to NVMmn may operate under control of the controller 16. For example, the nonvolatile memory device NVM11 may program the data DATAa (among the data DATAa to DATAm) based on the command CMDa and the address ADDRa provided to the first channel CH1. For example, based on the command CMDb (among the commands CMDa to CMDm) and the address ADDRb (among the addresses ADDRa to ADDRm) provided to the second channel CH2 (among the plurality of channels CH1 to CHm), the nonvolatile memory device NVM21 among the nonvolatile memory devices NVM11 to NVMmn may read the data DATAb and transmit the data DATAb to the controller 16.

FIG. 1 depicts that the memory device 17 communicates through m numbers of channels with the controller 16 and that the memory device 17 includes n numbers of nonvolatile memory devices for each channel, but the number of channels and the number of nonvolatile memory devices connected to one channel are variously changed.

In some embodiments, the controller 16 may include a semiconductor device (circuit), such as a processor, a NAND controller, and a host interface. The processor may control an overall operation of the electronic system 15 that includes the controller 16. The processor may operate based on certain firmware, and may control the NAND controller to access the memory device 17. The NAND controller may include a NAND interface that processes communication with the memory device 17. The NAND interface may transmit a control command for controlling the memory device 17, data to be written to memory cell transistors of the memory device 17, and data to be read from memory cell transistors of the memory device 17. The host interface may provide the electronic system 15 with communication with an external host. When a control command is received through the host interface from the external host, the memory device 17 may be controlled by the processor in response to the control command. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

In some embodiments, the electronic system 15 may communicate with the external host through one or more interfaces, such as universal serial bus (USB), peripheral component interconnect express (PCI-Express), serial advanced technology attachment (SATA), and/or M-PHY for universal flash storage (UFS). In some embodiments, the electronic system 15 may operate with power supplied through a connector from the external host. The electronic system 15 may further include a power management integrated circuit (PMIC) that distributes the power supplied from the external host to the controller 16 and the memory device 17.

In some embodiments, the electronic system 15 may further include a frequency boosting interface (FBI) circuit. The controller 16 may transceive signals in parallel with the memory device 17 through the FBI circuit. The FBI circuit may amplify frequencies of signals.

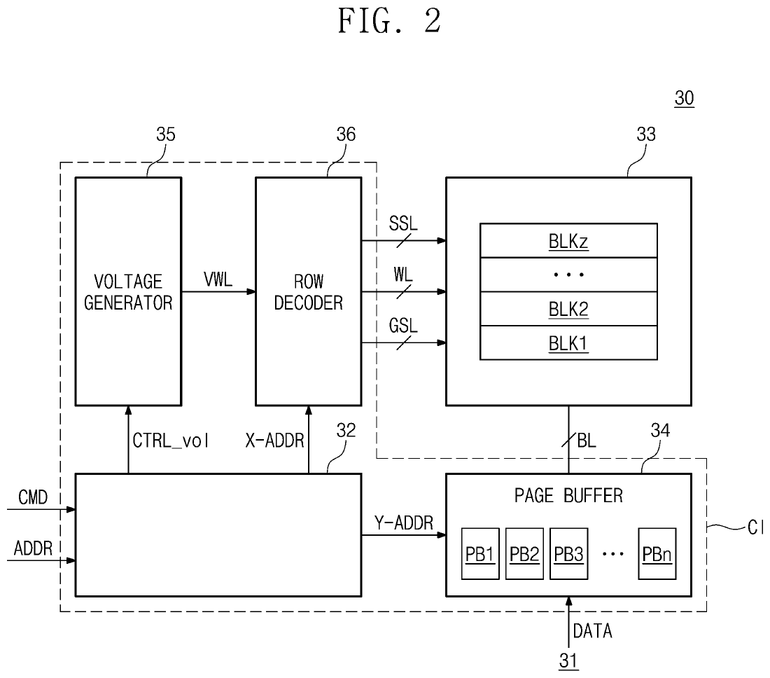

FIG. 2 illustrates a block diagram showing a memory device according to some embodiments.

Referring to FIG. 2, a memory device 30 may include a control logic circuit 32, a memory cell array 33, a page buffer 34, a voltage generator 35, and a row decoder 36. Although not shown in FIG. 2, the memory device 30 may further include an interface circuit 31, and may also further include a column logic, a pre-decoder, a temperature sensor, a command decoder, and an address decoder.

The control logic circuit 32 may generally control various kinds of operation of the memory device 30. In response to a command CMD and/or an address ADDR from the interface circuit 31, the control logic circuit 32 may output various kinds of control signal. For example, the control logic circuit 32 may output a voltage control signal CTRL_vol, a row address X-ADDR, and a column address Y-ADDR.

The memory cell array 33 may include a plurality of memory blocks BLK1 to BLKz (where, z is a positive integer), and each of the plurality of memory blocks BLK1 to BLKz may include a plurality of memory cells. The memory cell array 33 may be connected (e.g., electrically connected) to the page buffer 34 through bit lines BL, and may be connected (e.g., electrically connected) to the row decoder 36 through word lines WL, string selection lines SSL, and ground selection lines GSL.

In some embodiments, the memory cell array 33 may include a three-dimensional memory cell array, and the three-dimensional memory cell array may include a plurality of NAND strings. Each NAND string may include memory cells connected (e.g., electrically connected) to corresponding word lines that are vertically stacked on a substrate.

In some embodiments, the memory cell array 33 may include a two-dimensional memory cell array, and the two-dimensional memory cell array may include a plurality of NAND strings disposed along rows and columns.

The page buffer 34 may include a plurality of page buffers PB1 to PBn (where, n is an integer equal to or greater than 4), and the plurality of page buffers PB1 to PBn may be correspondingly connected (e.g., electrically connected) through the bit lines BL to the memory cells. In response to the column address Y-ADDR, the page buffer 34 may select at least one of the bit lines BL. The page buffer 34 may operate as a write driver or a sense amplifier according to an operating mode. For example, in a program operation, the page buffer 34 may provide the selected bit line (BL) with a bit-line voltage that corresponds to data which will be programmed. In a read operation, the page buffer 34 may detect a current or voltage of the selected bit line (BL) to sense data stored in the memory cell.

Based on the voltage control signal CTRL_vol, the voltage generator 35 may generate various kinds of voltage for performing a program, read, and erase operations. For example, the voltage generator 35 may generate a program voltage, a read voltage, a program verification voltage, and an erase voltage as a word-line voltage VWL.

In response to the row address X-ADDR, the row decoder 36 may select one of the word lines WL and one of the string selection lines SSL. For example, in a program operation, the row decoder 36 may apply a program voltage and a program verification voltage to the selected word line WL, and in a read operation, the row decoder 36 may apply a read voltage to the selected word line WL.

A driver circuit CI of the memory device 30 may be defined. In some embodiments, the driver circuit CI may include the control logic circuit 32, the page buffer 34, the voltage generator 35, and the row decoder 36.

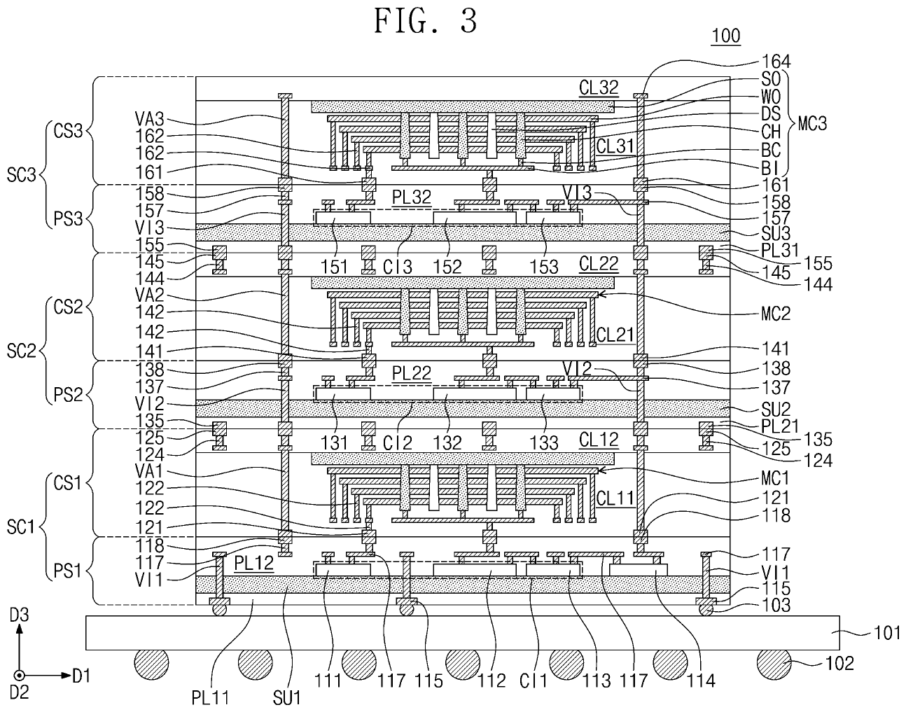

FIG. 3 illustrates a simplified cross-sectional view showing a semiconductor package according to some embodiments.

Referring to FIG. 3, a semiconductor package 100 may include a package substrate 101. The package substrate 101 may have a plate shape elongated along a plane defined by a first direction D1 and a second direction D2. The first direction D1 and the second direction D2 may intersect each other. For example, the first direction D1 and the second direction D2 may be horizontal directions orthogonal to each other. The first direction D1 and the second direction D2 may be parallel with a lower surface of subsequently described first peripheral circuit structure PS1 (e.g., a lower surface of subsequently described first lower peripheral dielectric layer PL11). In some embodiments, the electronic system 15 of FIG. 1 may include the semiconductor package 100.

The package substrate 101 may be a printed circuit board, a redistribution substrate including a photo-imageable dielectric layer, an interposer including a semiconductor substrate (e.g., a silicon substrate), or a semiconductor chip including a semiconductor device.

In some embodiments, the package substrate 101 may include a dynamic random access memory (DRAM). The DRAM may be a buffer memory that alleviates a difference in speed between an external host and first, second, and third semiconductor chips SC1, SC2, and SC3. The DRAM may serve as a kind of cache memory, and may provide a space to temporarily store data in an operation for controlling the first, second, and third semiconductor chips SC1, SC2, and SC3. When the package substrate 101 includes the DRAM, a subsequently described controller 114 may further include a DRAM controller for controlling the DRAM.

In some embodiments, the package substrate 101 may include a logic semiconductor device. The package substrate 101 may be (may include), for example, a central processing unit (CPU), a graphic processing unit (GPU), or an application processor (AP).

The package substrate 101 may be provided with terminals 102 connected to a lower (e.g., the lowermost) surface thereof. The semiconductor package 100 may be electrically connected through the terminals 102 to an external apparatus. The terminals 102 may include a conductive material.

The first semiconductor chip SC1, the second semiconductor chip SC2, and the third semiconductor chip SC3 may be (sequentially) mounted on the package substrate 101. The number of the semiconductor chips SC1, SC2, and SC3 may not be limited to that shown in FIG. 3. Bumps 103 may be provided between the first semiconductor chip SC1 and the package substrate 101. The first semiconductor chip SC1 may be electrically connected through the bumps 103 to the package substrate 101. The bumps 103 may include a conductive material.

The first semiconductor chip SC1 may include a first peripheral circuit structure PS1 and a first memory cell structure CS1 on the first peripheral circuit structure PS1. The first peripheral circuit structure PS1 may include a first lower peripheral dielectric layer PL11, a first substrate SU1 on the first lower peripheral dielectric layer PL11, a first upper peripheral dielectric layer PL12 on the first substrate SU1, a first driver circuit CI1, a controller 114, first lower peripheral pads 115, first through vias VI1, first peripheral conductive structures 117, and first upper peripheral pads 118. In some embodiments, the controller 114 may be included in the second semiconductor chip SC2 or the third semiconductor chip SC3.

The first lower peripheral dielectric layer PL11 may include a dielectric material. In some embodiments, the first lower peripheral dielectric layer PL11 may be a multiple layer including a plurality of dielectric layers.

The first lower peripheral pads 115 may be provided in the first lower peripheral dielectric layer PL11. The first lower peripheral pads 115 may be (at least partially) surrounded by the first lower peripheral dielectric layer PL11. The first lower peripheral pad 115 may be in contact with the bump 103. The first lower peripheral pad 115 may include a conductive material.

The first substrate SU1 may be provided on the first lower peripheral dielectric layer PL11. The first substrate SU1 may be a semiconductor substrate, a dielectric substrate, a silicon-on-insulator (SOI) substrate, or a germanium-on-insulator (GOI) substrate. The semiconductor substrate may include, for example, silicon (Si), germanium (Ge), silicon-germanium (SiGe), gallium phosphate (GaP), and/or gallium arsenide (GaAs).

The first upper peripheral dielectric layer PL12 may be provided on the first substrate SU1. The first upper peripheral dielectric layer PL12 may include a dielectric material. In some embodiments, the first upper peripheral dielectric layer PL12 may be a multiple layer including a plurality of dielectric layers.

The first driver circuit CI1 and the controller 114 may be provided on the first substrate SU1. The first driver circuit CI1 may include a first row decoder 111, a first page buffer 112, and a first control logic circuit 113. In some embodiments, the first peripheral circuit structure PS1 may further include a frequency boosting interface (FBI) on the first substrate SU1. The first upper peripheral dielectric layer PL12 may be on (e.g., may cover or may overlap) the first driver circuit CI1 and the controller 114. For example, the first upper peripheral dielectric layer PL12 may overlap the first driver circuit CI1 and the controller 114 in a third direction D3. The third direction D3 may be a vertical direction perpendicular to the lower surface of the first peripheral circuit structure PS1 (e.g., the lower surface of the first lower peripheral dielectric layer PL11). As used herein, “an element A overlapping an element B in a direction X” (or similar language) means that there is at least one line that extends in the direction X and intersects both the elements A and B.

The first peripheral conductive structures 117 may be provided in the first upper peripheral dielectric layer PL12. The first peripheral conductive structures 117 may be (at least partially) surrounded by the first upper peripheral dielectric layer PL12. The first peripheral conductive structures 117 may include at least one selected from a conductive pad, a conductive contact, and a conductive line. The first peripheral conductive structures 117 may include a conductive material.

The first through vias VI1 may extend in the third direction D3 in (e.g., to penetrate) the first substrate SU1. A lower (e.g., the lowermost) surface of the first through via VI1 may be located at a level lower than that of a lower (e.g., the lowermost) surface of the first substrate SU1. The level may be a relative location (e.g., distance) from the upper surface of the package substrate 101 in the third direction D3. For example, the lower surface of the first through via VI1 may be closer than the lower surface of the first substrate SU1 to the upper surface of the package substrate 101 in the third direction D3. An upper (e.g., the uppermost) surface of the first through via VI1 may be located at a level higher than that of an upper (e.g., the uppermost) surface of the first substrate SU1. For example, the upper surface of the first through via VI1 may be farther than the upper surface of the first substrate SU1 from the upper surface of the package substrate 101 in the third direction D3. The lower (e.g., the lowermost) surface of the first through via VI1 may be in contact with an upper (e.g., the uppermost) surface of the first lower peripheral pad 115. In some embodiments, the first through via VI1 and the first lower peripheral pad 115 may be spaced apart from each other, and a conductive structure may be provided to electrically connect the first through via VI1 and the first lower peripheral pad 115 to each other. The upper (e.g., the uppermost) surface of the first through via VI1 may be in contact with a lower (e.g., the lowermost) surface of the first peripheral conductive structures 117. The first through vias VI1 may include a conductive material.

The first upper peripheral pads 118 may be provided in the first upper peripheral dielectric layer PL12. The first upper peripheral pads 118 may be (at least partially) surrounded by the first upper peripheral dielectric layer PL12. A lower (e.g., the lowermost) surface of the first upper peripheral pad 118 may be in contact with an upper (e.g., the uppermost) surface of the first peripheral conductive structure 117. The first upper peripheral pad 118 may include a conductive material.

The first memory cell structure CS1 may be hybrid-bonded to the first peripheral circuit structure PS1. The first memory cell structure CS1 may include a first lower cell dielectric layer CL11, a first upper cell dielectric layer CL12, first lower cell pads 121, first lower cell conductive structures 122, a first memory cell array MC1, first connection vias VA1, first upper cell conductive structures 124, and first upper cell pads 125.

The first lower cell dielectric layer CL11 may be provided on the first upper peripheral dielectric layer PL12. A lower (e.g., the lowermost) surface of the first lower cell dielectric layer CL11 may be in contact with an upper (e.g., the uppermost) surface of the first upper peripheral dielectric layer PL12. The first lower cell dielectric layer CL11 may include a dielectric material. In some embodiments, the first lower cell dielectric layer CL11 may be a multiple layer including a plurality of dielectric layers.

The first lower cell pads 121 may be provided in the first lower cell dielectric layer CL11. The first lower cell pads 121 may be (at least partially) surrounded by the first lower cell dielectric layer CL11. A lower (e.g., the lowermost) surface of the first lower cell pad 121 may be in contact with the first upper peripheral pad 118. The first lower cell pad 121 and the first lower cell dielectric layer CL11 may be hybrid-bonded to the first upper peripheral pad 118 and the first upper peripheral dielectric layer PL12. The first lower cell pad 121 may include a conductive material.

The first lower cell conductive structures 122 may be provided in the first lower cell dielectric layer CL11. The first lower cell conductive structures 122 may be surrounded by the first lower cell dielectric layer CL11. The first lower cell conductive structures 122 may include at least one selected from a conductive pad, a conductive contact, and a conductive line. The first lower cell conductive structures 122 may include a conductive material.

The first connection vias VA1 may extend in the third direction D3. A lower (e.g., the lowermost) surface of the first connection via VA1 may be in contact with an upper (e.g., the uppermost) surface of the first lower cell pad 121. In some embodiments, the first connection via VA1 and the first lower cell pad 121 may be spaced apart from each other, and a conductive structure may be provided to electrically connect the first connection via VA1 and the first lower cell pad 121 to each other. An upper (e.g., the uppermost) surface of the first connection via VA1 may be in contact with a lower (e.g., the lowermost) surface of the first upper cell conductive structure 124. The first connection vias VA1 may include a conductive material.

The first memory cell array MC1, a subsequently described second memory cell array MC2, and a subsequently described third memory cell array MC3 may include word lines WO, bit lines BI, bit-line contacts BC, memory channel structures CH, separation structures DS, and a source structure SO.

The word lines WO may be stacked in the third direction D3. The memory channel structures CH may extend in the third direction D3 to extend in (e.g., penetrate) the word lines WO. The memory channel structure CH may include a channel layer and a memory layer that (at least partially) surrounds the channel layer. The channel layer may include a conductive material. For example, the channel layer may include polysilicon. The memory layer may include a tunnel dielectric layer that (at least partially) surrounds the channel layer, a data storage layer that (at least partially) surrounds the tunnel dielectric layer, and a blocking layer that (at least partially) surrounds the data storage layer. The tunnel dielectric layer and the blocking layer may include a dielectric material. For example, the tunnel dielectric layer and the blocking layer may include oxide. The data storage layer may include a material capable of trapping charges. For example, the data storage layer may include nitride. In some embodiments, the data storage layer may include a ferroelectric material, a floating gate electrode, or conductive nano-dots.

The separation structure DS may extend in the third direction D3 to extend in (e.g., penetrate) the word lines WO. The separation structures DS may include a dielectric material. In some embodiments, the separation structure DS may further include a conductive material (at least partially) surrounded by the dielectric material.

The source structure SO may be provided between the word line WO and a corresponding one of upper cell dielectric layers CL12, CL22, and CL32. The source structure SO may be electrically connected to the memory channel structure CH. The source structure SO may include a common source line. The source structure SO may include a conductive material. For example, the source structure SO may include polysilicon.

A corresponding one of lower cell conductive structures 122, 142, and 162 may be connected (e.g., electrically connected) to the word line WO. The bit-line contact BC may connect (e.g., electrically connect) the memory channel structure CH to the bit line BI.

The first lower cell dielectric layer CL11 may (at least partially) surround the word line WO, the memory channel structure CH, the separation structure DS, the source structure SO, the bit line BI, the bit-line contact BC, and the first connection via VA1.

The first upper cell conductive structures 124 may be provided in the first upper cell dielectric layer CL12. The first upper cell conductive structures 124 may be surrounded by the first upper cell dielectric layer CL12. The first upper cell conductive structures 124 may include at least one selected from a conductive pad, a conductive contact, and a conductive line. The first upper cell conductive structures 124 may include a conductive material.

The first upper cell pads 125 may be provided in the first upper cell dielectric layer CL12. The first upper cell pads 125 may be (at least partially) surrounded by the first upper cell dielectric layer CL12. The first upper cell pad 125 may include a conductive material.

The first row decoder 111 may control the word line WO of the first memory cell array MC1 through the first peripheral conductive structure 117, the first upper peripheral pad 118, the first lower cell pad 121, and the first lower cell conductive structure 122. The first page buffer 112 may control the memory channel structure CH of the first memory cell array MC1 through the first peripheral conductive structure 117, the first upper peripheral pad 118, the first lower cell pad 121, the first lower cell conductive structure 122, the bit line BI, and the bit-line contact BC.

The first control logic circuit 113 may control the first row decoder 111 and the first page buffer 112 through the first peripheral conductive structure 117. The controller 114 may be electrically connected through the first peripheral conductive structure 117 to the first control logic circuit 113 of the first driver circuit CI1.

The second semiconductor chip SC2 may be provided on the first semiconductor chip SC1. The second semiconductor chip SC2 may be hybrid-bonded to the first semiconductor chip SC1. In some embodiments, the second semiconductor chip SC2 may be connected (e.g., electrically connected) through bumps to the first semiconductor chip SC1. The second semiconductor chip SC2 may include a second peripheral circuit structure PS2 and a second memory cell structure CS2 on the second peripheral circuit structure PS2. The second peripheral circuit structure PS2 may be hybrid-bonded to the first memory cell structure CS1.

The second peripheral circuit structure PS2 may include a second lower peripheral dielectric layer PL21, a second substrate SU2 on the second lower peripheral dielectric layer PL21, a second upper peripheral dielectric layer PL22 on the second substrate SU2, a second driver circuit CI2, second lower peripheral pads 135, second through vias VI2, second peripheral conductive structures 137, and second upper peripheral pads 138.

The second lower peripheral dielectric layer PL21 may be provided on the first upper cell dielectric layer CL12. A lower (e.g., the lowermost) surface of the second lower peripheral dielectric layer PL21 may be in contact with an upper (e.g., the uppermost) surface of the first upper cell dielectric layer CL12. The second lower peripheral dielectric layer PL21 may include a dielectric material.

The second lower peripheral pads 135 may be provided on (in) the second lower peripheral dielectric layer PL21. A lower (e.g., the lowermost) surface of the second lower peripheral pad 135 may be in contact with an upper (e.g., the uppermost) surface of the first upper cell pad 125. The second lower peripheral pads 135 may include a conductive material.

The second substrate SU2 may be a semiconductor substrate, a dielectric substrate, a silicon-on-insulator (SOI) substrate, or a germanium-on-insulator (GOI) substrate. The second upper peripheral dielectric layer PL22 may include a dielectric material.

The second driver circuit CI2 may be provided on the second substrate SU2. The second driver circuit CI2 may include second row decoder 131, a second page buffer 132, and a second control logic circuit 133.

The second peripheral conductive structures 137 may be provided in the second upper peripheral dielectric layer PL22. The second peripheral conductive structures 137 may include a conductive material.

The second through vias VI2 may extend in the third direction D3 in (e.g., to penetrate) the second substrate SU2. A lower (e.g., the lowermost) surface of the second through via VI2 may be in contact with an upper (e.g., the uppermost) surface of the second lower peripheral pad 135. An upper (e.g., the uppermost) surface of the second through via VI2 may be in contact with a lower (e.g., the lowermost) surface of the second peripheral conductive structure 137. The second through vias VI2 may include a conductive material.

The second upper peripheral pads 138 may be provided in the second upper peripheral dielectric layer PL22. A lower (e.g., the lowermost) surface of the second upper peripheral pad 138 may be in contact with an upper (e.g., the uppermost) surface of the second peripheral conductive structure 137. The second upper peripheral pad 138 may include a conductive material.

The second memory cell structure CS2 may be hybrid-bonded to the second peripheral circuit structure PS2. A configuration of the second memory cell structure CS2 may be similar to that of the first memory cell structure CS1. The second memory cell structure CS2 may include a second lower cell dielectric layer CL21, a second upper cell dielectric layer CL22, second lower cell pads 141, second lower cell conductive structures 142, a second memory cell array MC2, second connection vias VA2, second upper cell conductive structures 144, and second upper cell pads 145.

The second row decoder 131 may control the word line WO of the second memory cell array MC2 through the second peripheral conductive structure 137, the second upper peripheral pad 138, the second lower cell pad 141, and the second lower cell conductive structure 142. The second page buffer 132 may control the memory channel structure CH of the second memory cell array MC2 through the second peripheral conductive structure 137, the second upper peripheral pad 138, the second lower cell pad 141, the second lower cell conductive structure 142, the bit line BI, and the bit-line contact BC.

The second control logic circuit 133 may control the second row decoder 131 and the second page buffer 132 through the second peripheral conductive structure 137. The controller 114 may be electrically connected to the second control logic circuit 133 of the second driver circuit CI2 through the first peripheral conductive structure 117, the first upper peripheral pad 118, the first lower cell pad 121, the first connection via VA1, the first upper cell conductive structure 124, the first upper cell pad 125, the second lower peripheral pad 135, the second through via VI2, and the second peripheral conductive structure 137.

The third semiconductor chip SC3 may be provided on the second semiconductor chip SC2. The third semiconductor chip SC3 may be hybrid-bonded to the second semiconductor chip SC2. In some embodiments, the third semiconductor chip SC3 may be connected (e.g., electrically connected) through bumps to the second semiconductor chip SC2. The third semiconductor chip SC3 may include a third peripheral circuit structure PS3 and a third memory cell structure CS3 on the third peripheral circuit structure PS3. The third peripheral circuit structure PS3 may be hybrid-bonded to the second memory cell structure CS2.

A configuration of the third peripheral circuit structure PS3 may be similar to that of the second peripheral circuit structure PS2. The third peripheral circuit structure PS3 may include a third lower peripheral dielectric layer PL31, a third substrate SU3, a third upper peripheral dielectric layer PL32, a third driver circuit CI3, third lower peripheral pads 155, third through vias VI3, third peripheral conductive structures 157, and third upper peripheral pads 158.

A configuration of the third memory cell structure CS3 may be similar to that of the first memory cell structure CS1. The third memory cell structure CS3 may include a third lower cell dielectric layer CL31, a third upper cell dielectric layer CL32, third lower cell pads 161, third lower cell conductive structures 162, a third memory cell array MC3, third connection vias VA3, third upper cell conductive structures 164.

The third row decoder 151 may control the word line WO of the third memory cell array MC3 through the third peripheral conductive structure 157, the third upper peripheral pad 158, the third lower cell pad 161, and the third lower cell conductive structure 162. The third page buffer 152 may control the memory channel structure CH of the third memory cell array MC3 through the third peripheral conductive structure 157, the third upper peripheral pad 158, the third lower cell pad 161, the third lower cell conductive structure 162, the bit line BI, and the bit-line contact BC.

The third control logic circuit 153 may control the third row decoder 151 and the third page buffer 152 through the third peripheral conductive structure 157. The controller 114 may be electrically connected to the third control logic circuit 153 of the third driver circuit CI3 through the first peripheral conductive structure 117, the first upper peripheral pad 118, the first lower cell pad 121, the first connection via VA1, the first upper cell conductive structure 124, the first upper cell pad 125, the second lower peripheral pad 135, the second through via VI2, the second peripheral conductive structure 137, the second upper peripheral pad 138, the second lower cell pad 141, the second connection via VA2, the second upper cell conductive structure 144, the second upper cell pad 145, the third lower peripheral pad 155, the third through via VI3, and the third peripheral conductive structure 157.

The first connection via VA1, the second through via VI2, the second connection via VA2, the third through via VI3, and the third connection via VA3 may overlap in the third direction D3 with each other. The first through via VI1 may not overlap in the third direction D3 with any of the first connection via VA1, the second through via VI2, the second connection via VA2, the third through via VI3, and the third connection via VA3.

An arrangement structure of the first lower peripheral pads 115 may be different from that of the first upper peripheral pads 118, that of the first lower cell pads 121, that of the first upper cell pads 125, that of the second lower peripheral pads 135, that of the second upper peripheral pads 138, that of the second lower cell pads 141, that of the second upper cell pads 145, that of the third lower peripheral pads 155, that of the third upper peripheral pads 158, and that of the third lower cell pads 161.

In some embodiments, the first lower peripheral pads 115 may include a first lower peripheral pad 115 that overlaps in the third direction D3 with (at least one of) the first upper peripheral pad 118, the first lower cell pad 121, the first upper cell pad 125, the second lower peripheral pad 135, the second upper peripheral pad 138, the second lower cell pad 141, the second upper cell pad 145, the third lower peripheral pad 155, the third upper peripheral pad 158, and the third lower cell pad 161, and may also include a first lower peripheral pad 115 that does not overlap in the third direction D3 with any thereof.

A width in the first direction D1 of the first lower peripheral pad 115 may be different from that of the first upper peripheral pad 118, that of the first lower cell pad 121, that of the first upper cell pad 125, that of the second lower peripheral pad 135, that of the second upper peripheral pad 138, that of the second lower cell pad 141, that of the second upper cell pad 145, that of the third lower peripheral pad 155, that of the third upper peripheral pad 158, and that of the third lower cell pad 161.

A width in the second direction D2 of the first lower peripheral pad 115 may be different from that of the first upper peripheral pad 118, that of the first lower cell pad 121, that of the first upper cell pad 125, that of the second lower peripheral pad 135, that of the second upper peripheral pad 138, that of the second lower cell pad 141, that of the second upper cell pad 145, that of the third lower peripheral pad 155, that of the third upper peripheral pad 158, and that of the third lower cell pad 161.

In the semiconductor package 100 according to some embodiments, the first memory cell array MC1 of the first memory cell structure CS1 may be a single-level-cell (SLC) memory cell array, and the second and third memory cell arrays MC2 and MC3 of the second and third memory cell structures CS2 and CS3 may each be a multi-level-cell (MLC) memory cell array.

The single-level cell and the multi-level cell may be distinguished based on capacity of data capable of being stored in one memory cell. The single-level cell may store one bit per cell. The multi-level cell may store more than one bit per cell, for example, two bits per cell, three bits per cell, or four bits per cell.

The controller 114 and the first driver circuit CI1 may control the first memory cell array MC1 to be programmed in a single-level cell mode. The controller 114 and the second and third driver circuits CI2 and CI3 may respectively control the second and third memory cell arrays MC2 and MC3 to be programmed in a multi-level cell mode. In accordance with the difference in control manner, a structure of the first driver circuit CI1 may be different from those of the second and third driver circuits CI2 and CI3. For example, subcomponents (e.g., row decoder, page buffer, and control logic circuit), the number of the subcomponents, and the arrangement of the subcomponents of the first driver circuit CI1 may be different from those of the second and third driver circuits CI2 and CI3. For example, the size, location, and/or connection structure of the first driver circuit CI1 may be different from those of the second and third driver circuits CI1 and CI3.

In some embodiments, among the first, second, and third memory cell arrays MC1, MC2, and MC3, only the second memory cell array MC2 or only the third memory cell array MC3 may be a single-level-cell memory cell array.

In the semiconductor package 100 according to some embodiments, as the controller 114 is included in the first peripheral circuit structure PS1, there may be no requirement for a space (e.g., an extra space) in which the controller 114 is disposed. Accordingly, the semiconductor package 100 may have a relatively small size. For example, the controller 114 may overlap any (all) of the first, second, and third memory cell structures CS1, CS2, and CS3 and the second and third peripheral circuit structures PS2 and PS3 in the third direction D3.

In the semiconductor package 100 according to some embodiments, as the controller 114 is included in the first peripheral circuit structure PS1, a relatively small distance may be provided between the controller 114 and the first, second, and third driver circuits CI1, CI2, and CI3. Accordingly, the semiconductor package 100 may have an increased operating speed.

In the semiconductor package 100 according to some embodiments, the first peripheral circuit structure PS1 may have a configuration different from those of the second and third peripheral circuit structures PS2 and PS3, and if necessary, the first peripheral circuit structure PS1 may be designed to have various configurations.

In the semiconductor package 100 according to some embodiments, the first through via VI1 and the first lower peripheral pad 115 do not overlap any of the first, second, and third connection vias VA1, VA2, and VA3 and the second and third through vias VI2 and VI3 (in the third direction D3), and thus the first through via VI1 and the first lower peripheral pad 115 may each have a layout appropriate for the package substrate 101.

In the semiconductor package 100 according to some embodiments, as the first, second, and third semiconductor chips SC1, SC2, and SC3 are hybrid-bonded to each other, the semiconductor package 100 may have a relatively small height.

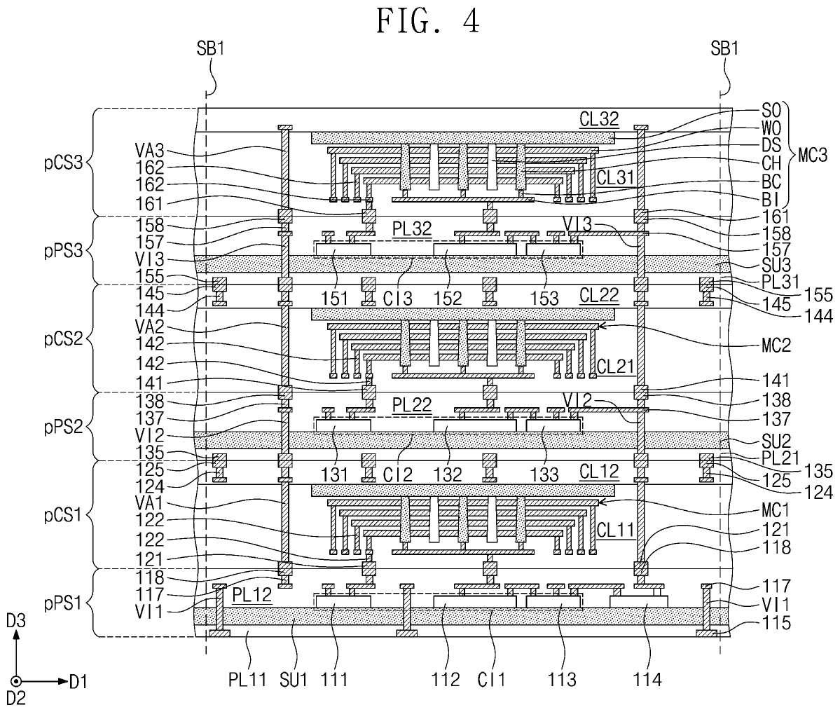

FIG. 4 illustrates a cross-sectional view showing a method of fabricating the semiconductor package according to FIG. 3.

Referring to FIG. 4, a first preliminary memory cell structure pCS1 may be hybrid-bonded to a first preliminary peripheral circuit structure pPS1. A second preliminary memory cell structure pCS2 may be hybrid-bonded to a second preliminary peripheral circuit structure pPS2. A third preliminary memory cell structure pCS3 may be hybrid-bonded to a third preliminary peripheral circuit structure pPS3. The second preliminary peripheral circuit structure pPS2 may be hybrid-bonded to the first preliminary memory cell structure pCS1. The third preliminary peripheral circuit structure pPS3 may be hybrid-bonded to the second preliminary memory cell structure pCS2.

A scribing process may be performed. The first preliminary peripheral circuit structure pPS1, the first preliminary memory cell structure pCS1, the second preliminary peripheral circuit structure pPS2, the second preliminary memory cell structure pCS2, the third preliminary peripheral circuit structure pPS3, and the third preliminary memory cell structure pCS3 may be cut along a scribing line SB1.

Referring to FIG. 3, the first preliminary peripheral circuit structure pPS1 may be cut and separated into a plurality of first peripheral circuit structures PS1. The first preliminary memory cell structure pCS1 may be cut and separated into a plurality of first memory cell structures CS1. The second preliminary peripheral circuit structure pPS2 may be cut and separated into a plurality of second peripheral circuit structures PS2. The second preliminary memory cell structure pCS2 may be cut and separated into a plurality of second memory cell structures CS2. The third preliminary peripheral circuit structure pPS3 may be cut and separated into a plurality of third peripheral circuit structures PS3. The third preliminary memory cell structure pCS3 may be cut and separated into a plurality of third memory cell structures CS3.

The first, second, and third semiconductor chips SC1, SC2, and SC3 may be (sequentially) mounted through bumps 103 on (an upper surface of) a package substrate 101. Terminals 102 may be formed on (a lower surface of) the package substrate 101.

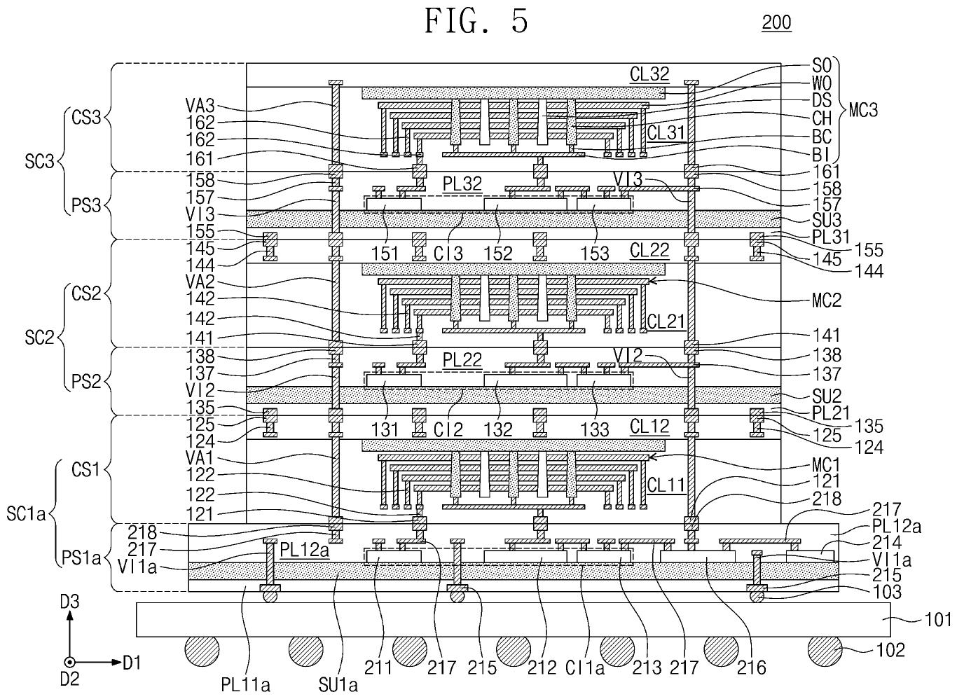

FIG. 5 illustrates a simplified cross-sectional view showing a semiconductor package according to some embodiments. Except that discussed below, a semiconductor package of FIG. 5 may be similar to the semiconductor package of FIG. 3.

Referring to FIG. 5, a first peripheral circuit structure PS1a of a first semiconductor chip SC1a may include a first lower peripheral dielectric layer PL11a, a first substrate SU1a, a first upper peripheral dielectric layer PL12a, a first driver circuit CI1a, a controller 214, a frequency boosting interface (FBI) circuit 216, first lower peripheral pads 215, first through vias VI1a, first peripheral conductive structures 217, and first upper peripheral pads 218.

A width in the first direction D1 of the first peripheral circuit structure PS1a may be greater than that of the first memory cell structure CS1, that of the second peripheral circuit structure PS2, that of the second memory cell structure CS2, the third peripheral circuit structure PS3, and that of the third memory cell structure CS3.

A width in the second direction D2 of the first peripheral circuit structure PS1a may be greater than that of the first memory cell structure CS1, that of the second peripheral circuit structure PS2, that of the second memory cell structure CS2, the third peripheral circuit structure PS3, and that of the third memory cell structure CS3.

The width in the first direction D1 of the first peripheral circuit structure PS1a may be less than that of the package substrate 101. The width in the second direction D2 of the first peripheral circuit structure PS1a may be less than that of the package substrate 101.

A width in the first direction D1 of the first substrate SU1a may be greater than those of the second and third substrates SU2 and SU3. A width in the second direction D2 of the first substrate SU1a may be greater than those of the second and third substrates SU2 and SU3.

The FBI circuit 216 may be provided on the first substrate SU1a. The controller 214 may be electrically connected through the first peripheral conductive structure 217 to the FBI circuit 216. The FBI circuit 216 may be electrically connected through the first peripheral conductive structure 217 to a control logic circuit 213 of the first driver circuit CI1a.

The FBI circuit 216 may be electrically connected to the second control logic circuit 133 of the second driver circuit CI2 through the first peripheral conductive structure 217, the first upper peripheral pad 218, the first lower cell pad 121, the first connection via VA1, the first upper cell conductive structure 124, the first upper cell pad 125, the second lower peripheral pad 135, the second through via VI2, and the second peripheral conductive structure 137.

The FBI circuit 216 may be electrically connected to the third control logic circuit 153 of the third driver circuit CI3 through the first peripheral conductive structure 217, the first upper peripheral pad 218, the first lower cell pad 121, the first connection via VA1, the first upper cell conductive structure 124, the first upper cell pad 125, the second lower peripheral pad 135, the second through via VI2, the second peripheral conductive structure 137, the second upper peripheral pad 138, the second lower cell pad 141, the second connection via VA2, the second upper cell conductive structure 144, the second upper cell pad 145, the third lower peripheral pad 155, the third through via VI3, and he third peripheral conductive structure 157.

In some embodiments, the first peripheral circuit structure PS1a may not include the FBI circuit 216.

The controller 214 may be disposed adjacent to a (an outer) sidewall of the first peripheral circuit structure PS1a, and may not overlap in the third direction D3 with any of the first, second, and third memory cell structures CS1, CS2, and CS3 and the second and third peripheral circuit structures PS2 and PS3. In some embodiments, differently from that shown, the FBI circuit 216 may be disposed adjacent to the (outer) sidewall of the first peripheral circuit structure PS1a, and may not overlap in the third direction D3 with any of the first, second, and third memory cell structures CS1, CS2, and CS3 and the second and third peripheral circuit structures PS2 and PS3.

In a semiconductor package 200 according to some embodiments, as the first peripheral circuit structure PS1a has a relatively large width (compared to that of the first, second, and third memory cell structures CS1, CS2, and CS3 and the second and third peripheral circuit structures PS2 and PS3), it may be possible to secure a space in which the controller 214 is disposed (without overlapping in the third direction D3 with any of the first, second, and third memory cell structures CS1, CS2, and CS3 and the second and third peripheral circuit structures PS2 and PS3).

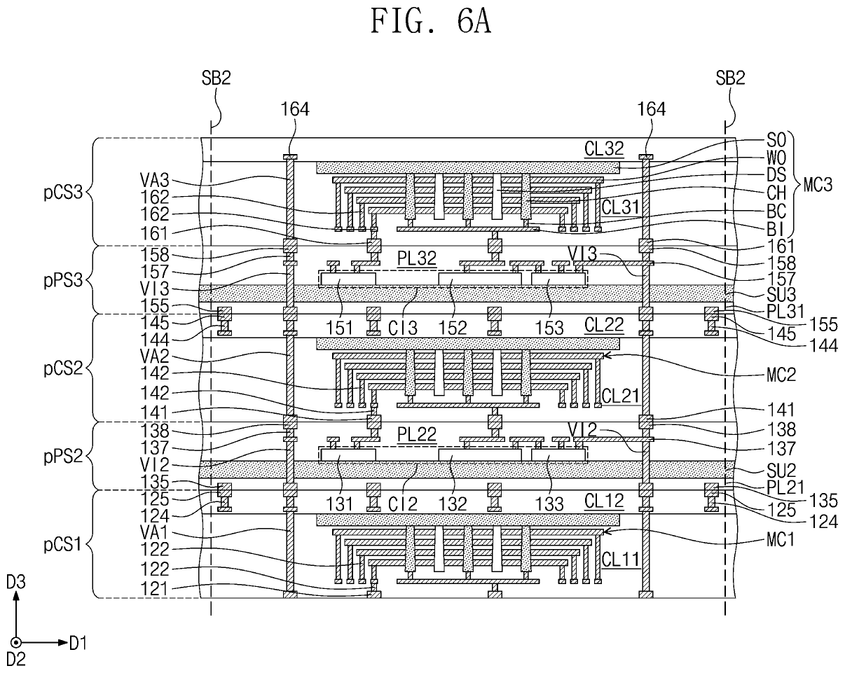

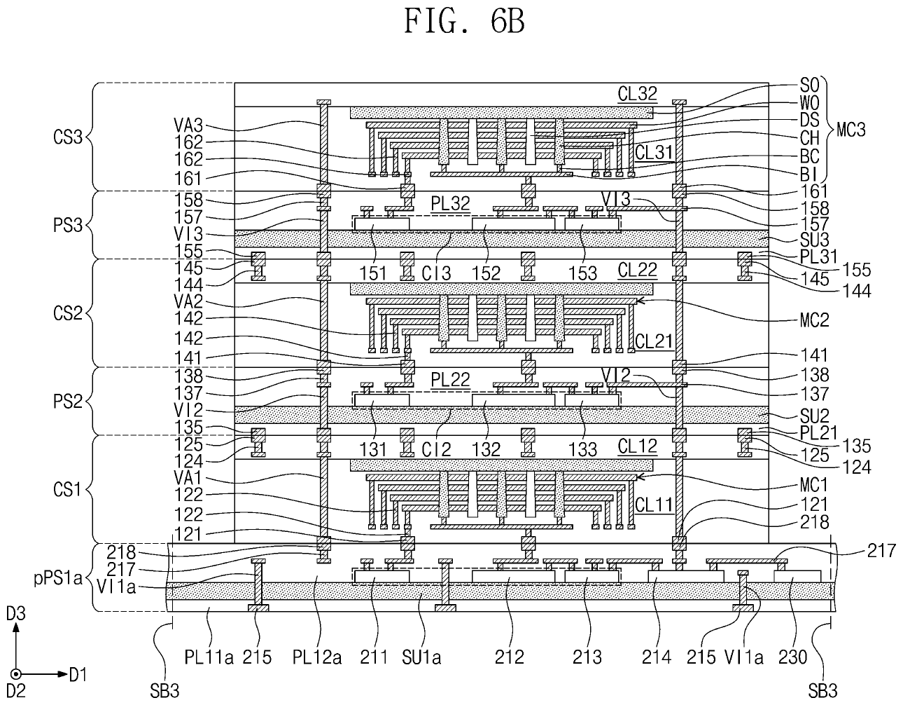

FIGS. 6A and 6B illustrate cross-sectional views showing a method of fabricating the semiconductor package according to FIG. 5.

Referring to FIG. 6A, a second preliminary memory cell structure pCS2 may be hybrid-bonded to a second preliminary peripheral circuit structure pPS2. A third preliminary memory cell structure pCS3 may be hybrid-bonded to a third preliminary peripheral circuit structure pPS3. The second preliminary peripheral circuit structure pPS2 may be hybrid-bonded to a first preliminary memory cell structure pCS1. The third preliminary peripheral circuit structure pPS3 may be hybrid-bonded to the second preliminary memory cell structure pCS2.

A scribing process may be performed. The first preliminary memory cell structure pCS1, the second preliminary peripheral circuit structure pPS2, the second preliminary memory cell structure pCS2, the third preliminary peripheral circuit structure pPS3, and the third preliminary memory cell structure pCS3 may be cut along a scribing line SB2.

Referring to FIG. 6B, the first preliminary memory cell structure pCS1 may be cut and separated into a plurality of first memory cell structures CS1. The second preliminary peripheral circuit structure pPS2 may be cut and separated into a plurality of second peripheral circuit structures PS2. The second preliminary memory cell structure pCS2 may be cut and separated into a plurality of second memory cell structures CS2. The third preliminary peripheral circuit structure pPS3 may be cut and separated into a plurality of third peripheral circuit structures PS3. The third preliminary memory cell structure pCS3 may be cut and separated into a plurality of third memory cell structures CS3.

The first memory cell structure CS1 may be hybrid-bonded to a first preliminary peripheral circuit structure pPS1a. A scribing process may be performed. The first preliminary peripheral circuit structure pPS1a may be cut along a scribing line SB3.

Referring to FIG. 5, the first preliminary peripheral circuit structure pPS1a may be cut and separated into a plurality of first peripheral circuit structures PS1a. A package substrate 101, bumps 103, and terminals 102 may be formed.

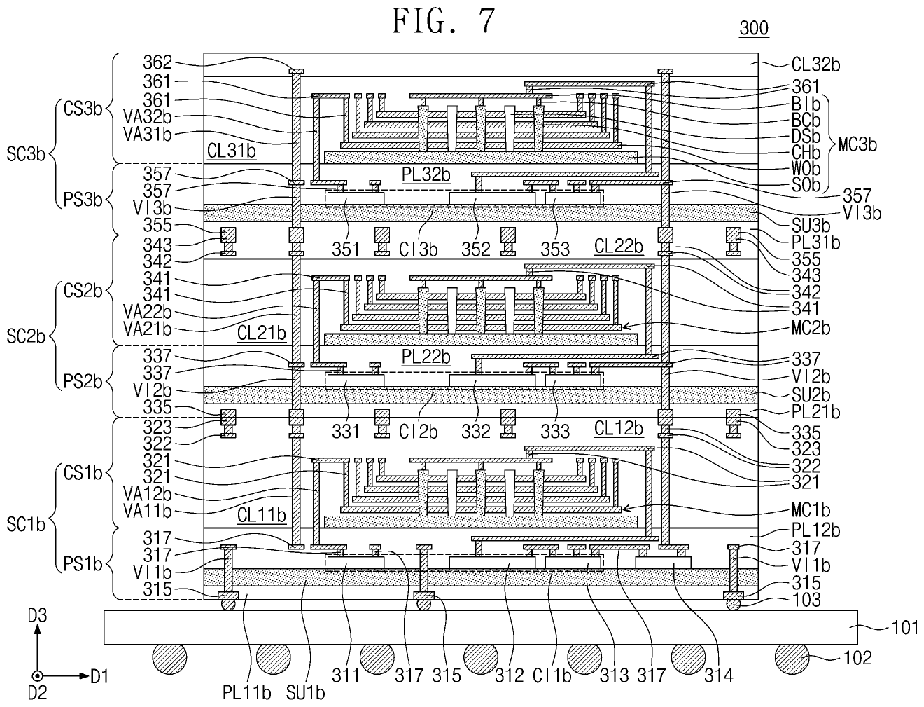

FIG. 7 illustrates a simplified cross-sectional view showing a semiconductor package according to some embodiments. Except that discussed below, a semiconductor package of FIG. 7 may be similar to the semiconductor package of FIG. 3.

Referring to FIG. 7, first, second, and third semiconductor chips SC1b, SC2b, and SC3b may be (sequentially) mounted on a package substrate 101.

The first semiconductor chip SC1b may include a first peripheral circuit structure PS1b and a first memory cell structure CS1b on the first peripheral circuit structure PS1b. The first peripheral circuit structure PS1b may include a first lower peripheral dielectric layer PL11b, a first substrate SU1b, a first upper peripheral dielectric layer PL12b, a first driver circuit CI1b, a controller 314, first lower peripheral pads 315, first through vias VI1b, and first peripheral conductive structures 317. The first driver circuit CI1b may include a first row decoder 311, a first page buffer 312, and a first control logic circuit 313.

The first memory cell structure CS1b may include a first lower cell dielectric layer CL11b, a first upper cell dielectric layer CL12b, first lower cell conductive structures 321, a first memory cell array MC1b, first connection vias VA11b, first conductive vias VA12b, first upper cell conductive structures 322, and first upper cell pads 323.

A lower (e.g., the lowermost) surface of the first connection via VA11b may be in contact with an upper (e.g., the uppermost) surface of the first peripheral conductive structure 317. An upper (e.g., the uppermost) surface of the first connection via VA11b may be in contact with a lower (e.g., the lowermost) surface of the first upper cell conductive structure 322.

A lower (e.g., the lowermost) surface of the first conductive via VA12b may be in contact with the upper (e.g., the uppermost) surface of the first peripheral conductive structure 317. An upper (e.g., the uppermost) surface of the first conductive via VA12b may be in contact with the lower (e.g., the lowermost) surface of the first lower cell conductive structure 321.

The first row decoder 311 may control a word line WOb of the first memory cell array MC1b through the first peripheral conductive structure 317, the first conductive via VA12b, and the first lower cell conductive structure 321. The first page buffer 312 may control a memory channel structure CHb of the first memory cell array MC1b through the first peripheral conductive structure 317, the first conductive via VA12b, the first lower cell conductive structure 321, a bit line BIb, and a bit-line contact BCb. The controller 314 may be electrically connected through the first peripheral conductive structure 317 to the first control logic circuit 313 of the first driver circuit CI1b.

The second semiconductor chip SC2b may include a second peripheral circuit structure PS2b and a second memory cell structure CS2b (on the second peripheral circuit structure PS2b). The second peripheral circuit structure PS2b may include a second lower peripheral dielectric layer PL21b, a second substrate SU2b, a second upper peripheral dielectric layer PL22b, a second driver circuit CI2b, second lower peripheral pads 335, second through vias VI2b, and second peripheral conductive structures 337. The second driver circuit CI2b may include second row decoder 331, a second page buffer 332, and a second control logic circuit 333.

A configuration of the second memory cell structure CS2b may be similar to that of the first memory cell structure CS1b. The second memory cell structure CS2b may include a second lower cell dielectric layer CL21b, a second upper cell dielectric layer CL22b, second lower cell conductive structures 341, a second memory cell array MC2b, second connection vias VA21b, second conductive vias VA22b, second upper cell conductive structures 342, and second upper cell pads 343.

The controller 314 may be electrically connected to a second control logic circuit 333 of the second driver circuit CI2b through the first peripheral conductive structure 317, the first connection via VA11b, the first upper cell conductive structure 322, the first upper cell pad 323, the second lower peripheral pad 335, the second through via VI2b, and the second peripheral conductive structure 337.

The third semiconductor chip SC3b may include a third peripheral circuit structure PS3b and a third memory cell structure CS3b (on the third peripheral circuit structure PS3b). The third peripheral circuit structure PS3b may include a third lower peripheral dielectric layer PL31b, a third substrate SU3b, a third upper peripheral dielectric layer PL32b, a third driver circuit CI3b, third lower peripheral pads 355, third through vias VI3b, and third peripheral conductive structures 357. The third driver circuit CI3b may include a third row decoder 351, a third page buffer 352, and a third control logic circuit 353.

A configuration of the third memory cell structure CS3b may be similar to that of the first memory cell structure CS1b. The third memory cell structure CS3b may include a third lower cell dielectric layer CL31b, a third upper cell dielectric layer CL32b, third lower cell conductive structures 361, a third memory cell array MC3b, third connection vias VA31b, third conductive vias VA32b, and third upper cell conductive structures 362.

Each of the first, second, and third memory cell arrays MC1b, MC2b, and MC3b may include word lines WOb, bit lines BIb, bit-line contacts BCb, memory channel structures CHb, separation structures DSb, and a source structure SOb. The source structure SOb may be provided between the word line WOb and a corresponding one of the upper peripheral dielectric layers PL12b, PL22b, and PL32b.

The controller 314 may be electrically connected to a third control logic circuit 353 of the third driver circuit CI3b through the first peripheral conductive structure 317, the first connection via VI11b, the first upper cell conductive structure 322, the first upper cell pad 323, the second lower peripheral pad 335, the second through via VI2b, the second peripheral conductive structure 337, the second connection via VA21b, the second upper cell conductive structure 342, the second upper cell pad 343, the third lower peripheral pad 355, the third through via VI3b, and the third peripheral conductive structure 357.

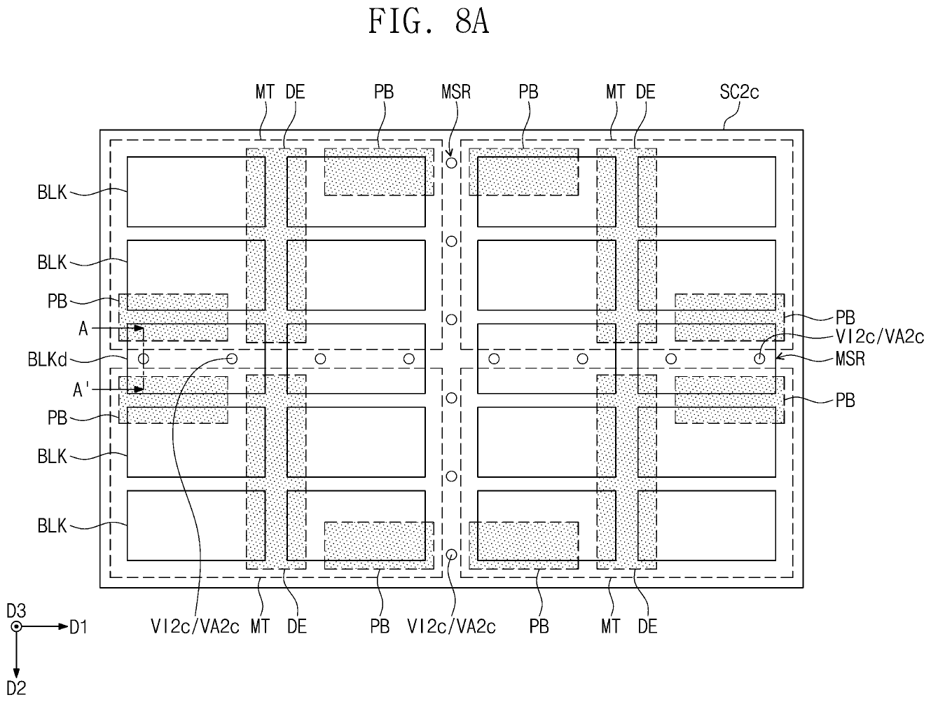

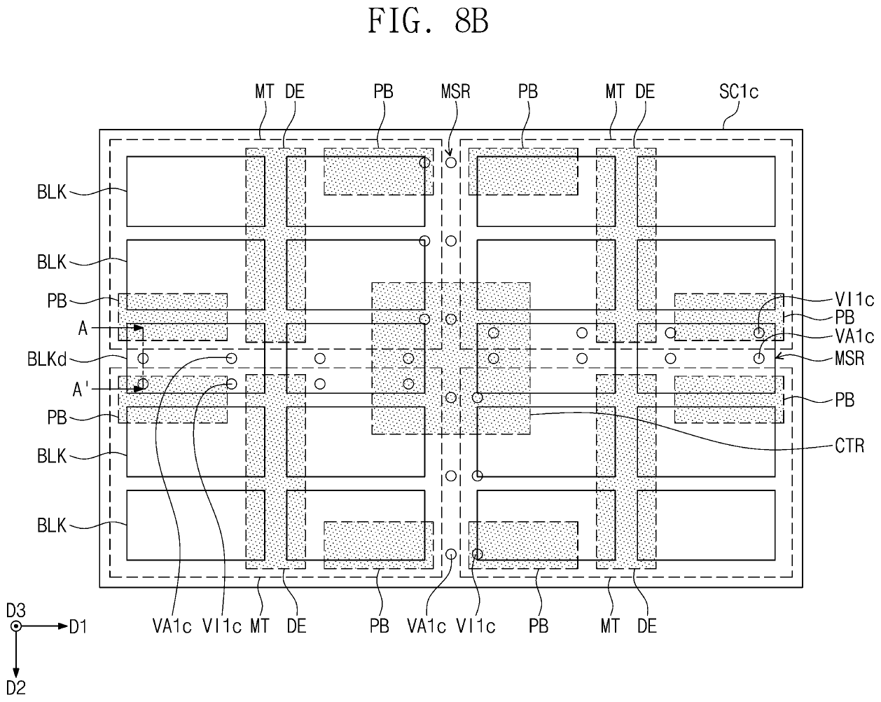

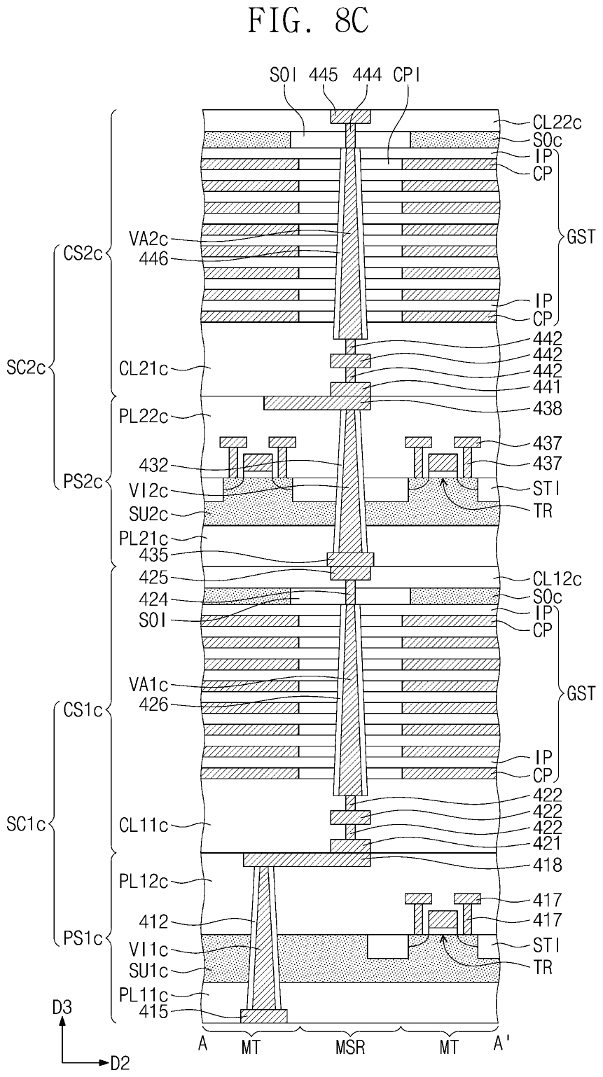

FIG. 8A illustrates a plan view showing a second semiconductor chip of a semiconductor package according to some embodiments. FIG. 8B illustrates a plan view showing a first semiconductor chip of a semiconductor package according to some embodiments. FIG. 8C illustrates a cross-sectional view taken along line A-A′ of FIGS. 8A and 8B.

Referring to FIGS. 8A and 8B, a first semiconductor chip SC1c and a second semiconductor chip SC2c of a semiconductor package according to some embodiments may include a plurality of mat regions MT and a mat separation region MSR between the mat regions MT. The mat separation region MSR may have a cross shape when viewed in plan.

The mat separation region MSR may include second connection vias VA2c and second through vias VI2c of the second semiconductor chip SC2c. The mat separation region MSR may include first connection vias VA1c of the first semiconductor chip SC1c. The mat region MT may include first through vias VI1c of the first semiconductor chip SC1c. In some embodiments, differently from that shown, the mat separation region MSR may include the first through vias VI1c of the first semiconductor chip SC1c.

Each of the first semiconductor chip SC1c and the second semiconductor chip SC2c may include page buffer regions PB and decoder regions DE. A page buffer may be disposed on the page buffer region PB. A row decoder may be disposed on the decoder region DE. The page buffer region PB and the decoder region DE may overlap in the third direction D3 with the mat region MT. Neither the page buffer region PB nor the decoder region DE may overlap in the third direction D3 with the mat separation region MSR.

The first semiconductor chip SC1c may further include a controller region CTR. A controller (e.g., the controller 114 in FIG. 3) may be disposed on (in) the controller region CTR. The controller region CTR may not overlap in the third direction D3 with any of the page buffer region PB and the decoder region DE. A structure and position of the controller region CTR may not be limited to that shown.

Each of the first semiconductor chip SC1c and the second semiconductor chip SC2c may include a plurality of blocks BLK and BLKd. The blocks BLK and BLKd may include memory blocks BLK and dummy blocks BLKd. A data storage operation, a data erase operation, and a data read operation may be actually performed on the memory blocks BLK. None of a data storage operation, a data erase operation, and a data read operation may be performed on the dummy blocks BLKd. The dummy blocks BLKd may overlap in the third direction D3 with the mat separation region MSR.

Referring to FIG. 8C, the first semiconductor chip SC1c may include a first peripheral circuit structure PS1c and a first memory cell structure CS1c (on the first peripheral circuit structure PS1c). The second semiconductor chip SC2c may include a second peripheral circuit structure PS2c and a second memory cell structure CS2c (on the second peripheral circuit structure PS2c).

The first peripheral circuit structure PS1c may include a first lower peripheral dielectric layer PL11c, a first lower peripheral pad 415, a first substrate SU1c, a transistor TR, a device isolation layer STI, first peripheral conductive structures 417, a first upper peripheral dielectric layer PL12c, a first through via VI1c, a first through via dielectric layer 412, and a first upper peripheral pad 418.

The transistor TR may be provided on (in) the first substrate SU1c. The transistor TR of the first peripheral circuit structure PS1c may constitute a page buffer, a row decoder, a control logic circuit, or a controller. In some embodiments, the page buffer, the row decoder, the control logic circuit, and/or the controller may include the transistor TR. The device isolation layer STI may be provided in the first substrate SU1c. The device isolation layer STI may include a dielectric material.

The first through via VI1c may be in contact with an upper (e.g., the uppermost) surface of the first lower peripheral pad 415 and a lower (e.g., the lowermost) surface of the first upper peripheral pad 418. The first through via dielectric layer 412 may (at least partially) surround the first through via VI1c.

The first memory cell structure CS1c may include a first lower cell dielectric layer CL11c, a first lower cell pad 421, first lower cell conductive structures 422, a gate stack structure GST, a source structure SOc, a source dielectric layer SOI, a first upper cell dielectric layer CL12c, a first upper cell conductive structure 424, a first upper cell pad 425, a first connection via VA1c, and a first connection via dielectric layer 426.

The gate stack structure GST may be provided on the first lower cell dielectric layer CL11c. The gate stack structure GST may include conductive patterns CP and dielectric patterns IP that are alternately stacked in the third direction D3.

The conductive patterns CP of the memory blocks BLK may include a word line, a string selection line, and a ground selection line. The conductive patterns CP of the dummy block BLKd may include dummy electrodes.

The gate stack structure GST of the dummy block BLKd may further include mold dielectric patterns CPI. The mold dielectric patterns CPI may (at least partially) surround the first connection via VA1c. The mold dielectric pattern CPI may be located at the same level as that of the conductive pattern CP. The mold dielectric pattern CPI may include a dielectric material having an etch selectivity with respect to the dielectric pattern IP. For example, the dielectric pattern IP may include oxide, and the mold dielectric pattern CPI may include nitride.

The first connection via VA1c may extend in (e.g., penetrate) the mold dielectric patterns CPI (and/or the conductive patterns CP) and the dielectric patterns IP of the gate stack structure GST. The first connection via VA1c may be in contact with a lower (e.g., the lowermost) surface of the first upper cell conductive structure 424 and an upper (e.g., the uppermost) surface of the first lower cell conductive structure 422. The first connection via dielectric layer 426 may (at least partially) surround the first connection via VA1c.

The source structure SOc may be provided on the gate stack structure GST. The source dielectric layer SOI may be located at the same level as that of the source structure SOc. The first upper cell conductive structure 424 may extend in (e.g., penetrate) the source dielectric layer SOI.

The second peripheral circuit structure PS2c may include a second lower peripheral dielectric layer PL21c, a second lower peripheral pad 435, a second substrate SU2c, a transistor TR, a device isolation layer STI, second peripheral conductive structures 437, a second upper peripheral dielectric layer PL22c, a second through via VI2c, a second through via dielectric layer 432, and a second upper peripheral pad 438.

The transistor TR of the second peripheral circuit structure PS2c may constitute a page buffer, a row decoder, a control logic circuit, or a controller. In some embodiments, the page buffer, the row decoder, the control logic circuit, and/or the controller may include the transistor TR.

The second memory cell structure CS2c may include a second lower cell dielectric layer CL21c, a second lower cell pad 441, second lower cell conductive structures 442, a gate stack structure GST, a source structure SOc, a source dielectric layer SOI, a second upper cell dielectric layer CL22c, a second upper cell conductive structure 444, a second upper cell pad 445, a second connection via VA2c, and a second connection via dielectric layer 446.

The first connection via VA1c, the second through via VI2c, and the second connection via VA2c may overlap in the third direction D3 with each other. The first through via VI1c and the first lower peripheral pad 415 may not overlap in the third direction D3 with any of the first connection via VA1c, the second through via VI2c, and the second connection via VA2c.

In a semiconductor package according to some embodiments of the present inventive concepts, as a controller is disposed in a peripheral circuit structure, the semiconductor package may have a relatively small size and an increased operating speed.

Although the present invention has been described in connection with some embodiments of the present inventive concepts illustrated in the accompanying drawings, it will be understood by one of ordinary skill in the art that variations in form and detail may be made therein without departing from the scope of the present inventive concepts. The above disclosed embodiments should thus be considered illustrative and not restrictive. Moreover, the embodiments discussed above may be combined with each other if necessary.

What is claimed is:

1. A semiconductor package, comprising:
a first semiconductor chip that includes a first peripheral circuit structure and a first memory cell structure on the first peripheral circuit structure; and
a second semiconductor chip that includes a second peripheral circuit structure and a second memory cell structure on the second peripheral circuit structure,
wherein the first peripheral circuit structure includes:
a first substrate;
a controller on the first substrate; and
a first driver circuit on the first substrate,
wherein the second peripheral circuit structure includes:
a second substrate; and
a second driver circuit on the second substrate,
wherein the controller is electrically connected to the first driver circuit and the second driver circuit.

2. The semiconductor package of claim 1, wherein the second peripheral circuit structure further includes a through via that extends in the second substrate, and
wherein the controller is electrically connected via the through via to the second driver circuit.

3. The semiconductor package of claim 1, wherein the first driver circuit includes a first row decoder, a first page buffer, and a first control logic circuit that are configured to control the first memory cell structure, and
wherein the second driver circuit includes a second row decoder, a second page buffer, and a second control logic circuit that are configured to control the second memory cell structure.

4. The semiconductor package of claim 1, wherein the first driver circuit and the controller are electrically connected to each other through the first peripheral circuit structure.

5. The semiconductor package of claim 1, wherein a connecting structure of the first driver circuit is different from a connecting structure of the second driver circuit.

6. The semiconductor package of claim 1, wherein the first memory cell structure includes a single-level-cell memory cell array, and
wherein the second memory cell structure includes a multi-level-cell memory cell array.

7. The semiconductor package of claim 1, wherein the first peripheral circuit structure includes a first lower peripheral pad and a first upper peripheral pad,
wherein the first memory cell structure includes a first upper cell pad and a first lower cell pad that is in contact with the first upper peripheral pad, and
wherein the second peripheral circuit structure includes a second lower peripheral pad that is in contact with the first upper cell pad.

8. The semiconductor package of claim 7, wherein the first upper peripheral pad overlaps the first lower cell pad, the first upper cell pad, and the second lower peripheral pad in a direction,
wherein the first lower peripheral pad is free of overlap with any of the first upper peripheral pad, the first lower cell pad, the first upper cell pad, and the second lower peripheral pad in the direction, and
wherein the direction is perpendicular to a lower surface of the first peripheral circuit structure.

9. The semiconductor package of claim 7, wherein a width of the first lower peripheral pad in a direction is different from a width of the first upper peripheral pad in the direction, a width of the first lower cell pad in the direction, a width of the first upper cell pad in the direction, and a width of the second lower peripheral pad in the direction, and
wherein the direction is parallel with a lower surface of the first peripheral circuit structure.

10. A semiconductor package, comprising:
a first semiconductor chip that includes a first peripheral circuit structure and a first memory cell structure on the first peripheral circuit structure; and
a second semiconductor chip that includes a second peripheral circuit structure and a second memory cell structure on the second peripheral circuit structure,
wherein the first memory cell structure includes a single-level-cell memory cell array, and
wherein the second memory cell structure includes a multi-level-cell memory cell array.

11. The semiconductor package of claim 10, further comprising a controller that is configured to control the first memory cell structure to be programmed in a single-level cell mode and the second memory cell structure to be programmed in a multi-level cell mode.

12. The semiconductor package of claim 11, wherein the controller is in the first peripheral circuit structure, and
wherein the controller overlaps at least one of the first memory cell structure, the second memory cell structure, and the second peripheral circuit structure in a direction that is perpendicular to a lower surface of the first peripheral circuit structure.

13. The semiconductor package of claim 10, wherein the first peripheral circuit structure includes a first driver circuit that is configured to control the first memory cell structure,
wherein the second peripheral circuit structure includes a second driver circuit that is configured to control the second memory cell structure, and
wherein a structure of the first driver circuit is different from a structure of the second driver circuit.

14. The semiconductor package of claim 10, wherein a width of the first peripheral circuit structure in a first direction is greater than a width of the second peripheral circuit structure in the first direction, and
wherein the first direction is parallel with a lower surface of the first peripheral circuit structure.

15. The semiconductor package of claim 14, wherein the first peripheral circuit structure includes a first substrate and a first driver circuit on the first substrate,
wherein the second peripheral circuit structure includes a second substrate and a second driver circuit on the second substrate, and
wherein a width of the first substrate in the first direction is greater than a width of the second substrate in the first direction.

16. The semiconductor package of claim 15, wherein the first peripheral circuit structure further includes a controller on the first substrate,
wherein the controller is electrically connected to the first driver circuit and the second driver circuit,
wherein the controller does not overlap any of the first memory cell structure, the second peripheral circuit structure, and the second memory cell structure in a second direction, and
wherein the second direction is perpendicular to the lower surface of the first peripheral circuit structure.

17. The semiconductor package of claim 16, wherein the second peripheral circuit structure further includes a through via that extends in the second substrate, and
wherein the controller is electrically connected via the through via to the second driver circuit.

18. The semiconductor package of claim 10, further comprising a third semiconductor chip that includes a third peripheral circuit structure and a third memory cell structure on the third peripheral circuit structure,
wherein the third memory cell structure includes a multi-level-cell memory cell array.

19. An electronic system, comprising:
a first semiconductor chip that includes a first peripheral circuit structure and a first memory cell structure on the first peripheral circuit structure; and
a second semiconductor chip that includes a second peripheral circuit structure and a second memory cell structure on the second peripheral circuit structure,
wherein the first peripheral circuit structure includes:
a first lower peripheral dielectric layer;
a first lower peripheral pad in the first lower peripheral dielectric layer;
a first substrate on the first lower peripheral dielectric layer;
a first through via that extends in the first substrate;
a first upper peripheral dielectric layer on the first substrate; and
a first upper peripheral pad in the first upper peripheral dielectric layer,
wherein the first memory cell structure includes:
a first lower cell dielectric layer on the first upper peripheral dielectric layer;
a first lower cell pad in the first lower cell dielectric layer;
a first upper cell dielectric layer on the first lower cell dielectric layer; and
a first upper cell pad in the first upper cell dielectric layer,
wherein the second peripheral circuit structure includes:
a second lower peripheral dielectric layer on the first upper cell dielectric layer;
a second lower peripheral pad in the second lower peripheral dielectric layer;
a second substrate on the second lower peripheral dielectric layer;
a second through via that extends in the second substrate;
a second upper peripheral dielectric layer on the second substrate; and
a second upper peripheral pad in the second upper peripheral dielectric layer,
wherein the second memory cell structure includes:
a second lower cell dielectric layer on the second upper peripheral dielectric layer; and
a second lower cell pad in the second lower cell dielectric layer,
wherein the first upper peripheral pad overlaps the first lower cell pad, the first upper cell pad, the second lower peripheral pad, the second upper peripheral pad, and the second lower cell pad in a direction,
wherein the first lower peripheral pad does not overlap any of the first upper peripheral pad, the first lower cell pad, the first upper cell pad, the second lower peripheral pad, the second upper peripheral pad, and the second lower cell pad in the direction, and
wherein the direction is perpendicular to a lower surface of the first lower peripheral dielectric layer.

20. The electronic system of claim 19, wherein the first through via is between the first lower peripheral pad and the first upper peripheral pad, and
wherein the second through via is between the second lower peripheral pad and the second upper peripheral pad.
